(19) United States
(12) Patent Application Publication
(10) Pub. No.: US 2025/0178978 A1
(43) Pub. Date: Jun. 5, 2025

(54) METAL-CERAMIC COMPOSITE

(71) Applicant: Heraeus Electronics GmbH & Co. KG, Hanau (DE)

(72) Inventors: Richard WACKER, Hanau (DE); Leszek NIEWOLAK, Hanau (DE); Stefanie STOICA, Hanau (DE); Carsten SCHAUER, Hanau (DE)

(21) Appl. No.: 18/962,463

(22) Filed: Nov. 27, 2024

(30) Foreign Application Priority Data
Nov. 30, 2023 (EP) 23213376.9

(51) Int. Cl. C04B 41/51; C04B 35/584

(52) U.S. Cl. CPC C04B 41/5155; C04B 35/584; C04B 41/5127; C04B 2235/3873

(57) ABSTRACT

A metal-ceramic composite containing a ceramic substrate comprising a front side and a rear side and containing silicon nitride, a metal coating on the front side of the ceramic substrate, wherein the metal coating has at least one recess, and a surface of the ceramic substrate is exposed by the recess, the ceramic substrate shows an Si2p signal in the range of 96 to 107 eV in an energy spectrum recorded by X-ray photoelectron spectroscopy (hereinafter also referred to as XPS spectrum), at least in the region of the recess, wherein the Si2p signal has the following: one or more peaks that each have a maximum in the range of 98.0 to 100.0 eV, one or more peaks that each have a maximum in the range of 101.0 to 102.2 eV, one or more peaks that each have a maximum in the range of 102.5 to 104.0 eV.

### CROSS-REFERENCE TO RELATED APPLICATIONS

This application claims priority pursuant to 35 U.S.C. 119 (a) to European Patent Application No. 23213376.9, filed Nov. 30, 2023, which application is incorporated herein by reference in its entirety.

### FIELD OF THE INVENTION

The present invention relates to a metal-ceramic composite which can be used as a ceramic circuit carrier in power electronics.

### BACKGROUND OF THE INVENTION

In power electronics, printed circuit boards must be designed for high currents as carriers for power components, such as MOSFETs, and be able to quickly dissipate waste heat.

Since ceramic materials, such as aluminum oxide, aluminum nitride, and silicon nitride, have a much higher thermal conductivity than polymers used to produce conventional printed circuit boards, ceramic circuit carriers are often used in power modules.

Ceramic substrates based upon silicon nitride have very high mechanical strength and at the same time high thermal conductivity and are therefore very suitable for applications in power electronics.

Ceramic substrates based on silicon nitride are described, for example, in the following publications:
N. Chasserio et al., “Ceramic Substrates for High-Temperature Electronic Integration,” Journal of Electronic Materials, Volume 38 (2009), pp. 164-174;
K. Hirao et al., “High Thermal Conductivity Silicon Nitride Ceramics,” Journal of the Korean Ceramic Society, Volume 49 (2012), pp. 380-384;
Y. Zhou et al., “Development of high-thermal-conductivity silicon nitride ceramics,” Journal of Asian Ceramic Societies, 3 (2015), pp. 221-229.

Silicon nitride-based ceramic substrates, which show a good compromise between high mechanical strength and high thermal conductivity and can be used in electronic components, are commercially available.

A ceramic circuit carrier contains a ceramic substrate which is provided with a metal layer on at least one of its sides, usually on both sides. In the final module, the semiconductor components are applied to one of these metal layers, while the metal layer on the opposite side of the ceramic substrate is thermally conductively connected to a heat sink. The ceramic substrate electrically insulates the metal layers from each other.

Known to a person skilled in the art, a metalized ceramic substrate functioning as a ceramic circuit board is produced, for example, by bringing the front and rear side of the ceramic substrate into contact with a metal film (e.g., a copper or aluminum film) and bonding them together. The material bonding of the metal foils is achieved, for example, by eutectic bonding or active metal brazing (AMB). If the metal film is a copper film, eutectic bonding is also referred to as the DCB or DBC method (DCB: “direct copper bonding”; DBC: “direct bonded copper”). In the case of aluminum film, the term “DAB” (“direct aluminum bonding”) is also used for eutectic bonding. A metalized ceramic substrate produced using a DCB or AMB process is sometimes also referred to as a DCB substrate (alternatively: DBC substrate) or AMB substrate.

The metalization of silicon nitride substrates is usually carried out by active metal brazing.

Active metal brazes contain, in addition to a main component, such as Cu, Ag or Au, one or more elements that can react with the ceramic to form an adhesion-promoting reaction layer (see, for example, Chapter 8.2.4.3 (“Active metal brazing”), pages 203-204, in Brevier Technische Keramik, Verband der Keramischen Industrie eV, 2003, Fahner Verlag). Reactive elements, such as hafnium (Hf), titanium (Ti), zirconium (Zr), niobium (Nb), cerium (Ce), tantalum (Ta), and vanadium (V), are used. In the metalization of silicon nitride substrates by active metal brazing, the reaction layer contains, for example, a nitride, oxynitride and/or silicide of the reactive element (A. Pönicke et al., “Active metal brazing of copper with aluminum nitride and silicon nitride ceramics,” Keramische Zeitschrift, 63 (5), 2011, 334-342).

The metal layer carrying the semiconductor components comprises one or more recesses and is therefore also referred to as a structured metal coating. By structuring, for example, metallic conductor tracks are formed on the ceramic substrate. Adjacent conductor tracks are spatially separated by the recesses and are therefore electrically insulated from each other. The structuring of AMB substrates can, for example, be carried out in a two-stage process, wherein, in a first step, the metal layer is first removed in defined regions (e.g., using a first etching solution), and then, in a second step, the adhesion-promoting layer resulting from the active metal brazing process is removed (e.g., using a second etching solution). By removing the metal layer and, if applicable, the adhesion-promoting layer, the ceramic substrate is exposed again in defined regions.

Modules based upon ceramic circuit carriers used in power electronics can be encapsulated as part of the packaging process, for example, by embedding the power module in a casting compound.

For example, embedding in a casting compound increases the electrical breakdown strength. In addition, the semiconductor components and metal conductor tracks are protected from humidity and mechanically stabilized.

In the regions exposed by the structuring, the ceramic substrate comes into direct contact with the casting compound. When operating a power module, significant temperature fluctuations can occur. Since ceramic materials and the casting compound usually have significantly different thermal expansion coefficients, these temperature fluctuations result in mechanical stresses at the interface between the ceramics and the casting compound. This in turn can result in the casting compound becoming at least partially detached from the ceramic substrate and in cavities forming. Humidity that penetrates these cavities can damage the power module. In addition, there may be a significant reduction in the electrical breakdown strength, at least locally. This is particularly problematic when moisture condenses in one of the recesses in the metal coating which separates the adjacent conductor tracks or chip carrier regions from one another.

As already mentioned above, ceramic substrates based upon silicon nitride are used as circuit carriers in power electronics due to their very high mechanical strength and high thermal conductivity. In order to make the most of their potential as circuit carriers, it would be desirable for there to be a high adhesion strength between the casting compound and the silicon nitride surface after embedding in a casting compound.

### SUMMARY OF THE INVENTION

An object of the present invention is to provide a metalized silicon nitride-containing ceramic substrate having improved moisture protection. In particular, moisture protection should still be provided even if the casting compound detaches from the ceramic surface in the region of a recess in the metal coating.

This object is achieved by a metal-ceramic composite containing
a ceramic substrate comprising a front side and a rear side and containing silicon nitride,
a metal coating on the front side of the ceramic substrate,
wherein
the metal coating has at least one recess, and a surface of the ceramic substrate is exposed by the recess,
the ceramic substrate shows an Si2p signal in the range of 96 to 107 eV in an energy spectrum recorded by X-ray photoelectron spectroscopy (hereinafter also referred to as XPS spectrum), at least in the region of the recess,
wherein the Si2p signal has the following:
one or more peaks that each have a maximum in the range of 98.0 to 100.0 eV,
one or more peaks that each have a maximum in the range of 101.0 to 102.2 eV,
one or more peaks that each have a maximum in the range of 102.5 to 104.0 eV.

### DETAILED DESCRIPTION OF THE INVENTION

The signal of an element in the XPS spectrum is influenced by its oxidation state and its chemical environment (e.g. its chemical bonding partners). For example, if the Si atoms present in a ceramic substrate have a uniform oxidation state and a consistent chemical environment, an Si2p signal with a relatively narrow half-width is to be expected in the XPS spectrum. This applies to conventional silicon nitride-based ceramic substrates. Even after contact with an etching medium, for example when removing a metal coating on the silicon nitride, the XPS spectrum usually shows an Sip signal with a small half-width.

Within the scope of the present invention, it was recognized that the treatment of the ceramic substrate with an ultrashort pulse laser can lead to a significant increase in the hydrophobicity of the treated silicon nitride surface. This manifests, for example, in a significant increase in the wetting angle for water in comparison with an untreated silicon nitride ceramic or one contacted with an etching medium. This leads to improved moisture protection of the silicon nitride ceramic.

Furthermore, it was recognized within the scope of the present invention that, in the Si2p signal of the XPS spectrum of the silicon nitride surface hydrophobized by the laser treatment, additional peaks appear that are not present in the Si2p signal of the silicon nitride ceramic which is untreated or is treated with an etching medium.

In the XPS spectra of the untreated silicon nitride ceramic and the silicon nitride ceramic contacted with an etching medium, the Si2p signal substantially shows only one peak, the maximum of which lies in the range of 101.0 to 102.2 eV. In the XPS spectra of the silicon nitride ceramics that were treated with a pulsed laser and exhibit a significantly higher water wetting angle as a result of this treatment, additional peaks are observed in the Si2p signal, the maxima of which lie in the range of 98.0 to 100.0 eV and in the range of 102.5 to 104.0 eV.

For example, in the ranges of 98.0 to 100.0 eV, 101.0 to 102.2 eV and 102.5 to 104.0 eV there is at least one peak, but no more than two peaks, with a maximum in the relevant range.

In a further exemplary embodiment, in the ranges of 98.0 to 100.0 eV, 101.0 to 102.2 eV and 102.5 to 104.0 eV there is only a single peak with a maximum in the relevant range.

In an exemplary embodiment, the following applies:

$${I}_{1} / {I}_{ges} \geq 0.02 ;$$

$$2. \leq {I}_{2} / {I}_{1} \leq 8. ;$$

$$with the proviso that$$

$$( {I}_{1} + {I}_{2} ) / {I}_{ges} \leq 0 \text{.85} ;$$

$$( {I}_{1} + {I}_{2} + {I}_{3} ) / {I}_{ges} \geq 0 \text{.95} ;$$

where
I_{ges} is the total intensity of the Si2p signal;
I₁ is the total intensity of the peaks that each have a maximum in the range of 98.0-100.0 eV;
I₂ is the total intensity of the peaks that each have a maximum in the range of 101.0-102.2 eV;
I₃ is the total intensity of the peaks that each have a maximum in the range of 102.5-104.0 eV.

The total intensity I_{ges} of the Si2p signal results from the sum of the intensities of all the peaks from which the Si2p signal is composed.

The intensity of a peak is the area under that peak.

If there is only one peak with a maximum in the range of 98.0 to 100.0 eV of the Si2p signal, the total intensity I₁ corresponds to the intensity of this peak. If there are two peaks in total, each with a maximum in the range of 98.0 to 100.0 eV, the total intensity I₁ corresponds to the sum of the two peak intensities. The total intensities I₂ and I₃ are determined in the same way in the ranges of 101.0 to 102.2 eV and 102.5 to 104.0 eV.

For example, the following applies:

$${I}_{1} / {I}_{ges} \geq 0.05 ;$$

$$2.5 \leq {I}_{2} / {I}_{1} \leq 7.$$

$$with the proviso that$$

$$( {I}_{1} + {I}_{2} ) / {I}_{ges} \leq 0 \text{.80} ;$$

$$( {I}_{1} + {I}_{2} + {I}_{3} ) / {I}_{ges} \geq 0.95 .$$

In a further exemplary embodiment, the following applies:

$$2. \leq {I}_{2} / {I}_{1} \leq 8.$$

$$0.4 \leq ( {I}_{1} + {I}_{2} ) / {I}_{ges} \leq 0 \text{.85} ;$$

$$( {I}_{1} + {I}_{2} + {I}_{3} ) / {I}_{ges} \geq 0.95$$

For example, the following applies:

$$2.5 \leq {I}_{2} / {I}_{1} \leq 7.$$

$$0.5 \leq ( {I}_{1} + {I}_{2} ) / {I}_{ges} \leq 0 \text{.80} ;$$

$$( {I}_{1} + {I}_{2} + {I}_{3} ) / {I}_{ges} \geq 0.95$$

In a further exemplary embodiment, the following applies:

$$0.05 \leq {I}_{1} / {I}_{ges} \leq 0.2$$

$$0.2 \leq {I}_{2} / {I}_{ges} \leq 0 \text{.70} ;$$

$$( {I}_{1} + {I}_{2} + {I}_{3} ) / {I}_{ges} \geq 0.95 .$$

For example, the ceramic substrate contains the silicon nitride in a proportion of at least 70 wt. %, more preferably at least 80 wt. %.

The silicon nitride, for example, is present in the β-phase (β-silicon nitride).

Optionally, the ceramic substrate may contain one or more metal oxides. These were added, for example, as sintering aids during the production of the ceramic substrate. For example, the ceramic substrate contains one or more of the following oxides: one or more alkaline earth metal oxides such as magnesium oxide, one or more transition metal oxides (e.g., one or more rare earth oxides such as yttrium oxide or erbium oxide), a silicon oxide (e.g., SiO₂), or a silicate.

The ceramic substrate, for example, has a thickness in the range of 0.1 mm to 1.0 mm.

On the front side of the ceramic substrate, there is a metal coating which comprises at least one recess, so that a surface of the ceramic substrate is exposed by the recess. This metal coating is also referred to as structured metal coating. The semiconductor components can be attached to the structured metal coating.

Optionally, a metal coating is also available on the rear side of the ceramic substrate. This rear side metal coating can optionally also comprise at least one recess, through which a surface of the ceramic substrate is exposed. In order to achieve the most efficient heat dissipation possible, it may be preferable for the rear side metal coating not to comprise such a recess.

The metal coating present on the front side and optionally the rear side of the ceramic substrate is, for example, a copper coating or an aluminum coating. The metal coating has, for example, a thickness in the range of 0.05 mm to 1.5 mm, more preferably 0.2 mm to 0.8 mm.

If the metal coating is a copper coating, it has, for example, a copper content of at least 97 wt. %, more preferably at least 99 wt. %.

If the metal coating is an aluminum coating, it has, for example, an aluminum content of at least 97 wt. %, more preferably at least 99 wt. %.

The metal coating can be applied to the front side and optionally the rear side of the ceramic substrate using methods known to a person skilled in the art.

For example, a metal foil (e.g., a copper or aluminum foil) is bonded to the front side of the ceramic substrate by active metal brazing.

In active metal brazing, for example, a connection is made between the metal foil and the ceramic substrate using an active metal braze at a temperature of approximately 600-1,000° C. Due to their alloy composition, active metal brazes are able to wet non-metallic, inorganic materials such as ceramic substrates. In addition to a main component such as copper, silver, and/or gold, active metal brazes also contain one or more active metals such as Hf, Ti, Zr, Nb, V, Ta, or Ce, which can react with the ceramic substrate to form a reaction layer.

Preferably, a reaction layer resulting from the active metal brazing is present between the metal coating and the front side of the ceramic substrate. The reaction layer contains, for example, one or more elements ERS, selected from Hf, Ti, Zr, Nb, V, Ta, and Ce, preferably selected from Hf, Ti, Zr, Nb, and Ce, more preferably selected from Hf, Ti, and Zr. The element ERS particularly preferred in the reaction layer is titanium. For example, the elements ERS are present in the reaction layer in the form of a nitride, oxynitride, and/or silicide. For example, the reaction layer contains the elements ERS in a total amount of at least 50 wt. %. For example, the reaction layer contains the nitrides, oxynitrides, and silicides of the elements ESR in a total amount of at least 70 wt. %, more preferably at least 85 wt. %. In a power electronics semiconductor module, the migration of silver can cause problems. It may therefore be preferred that the reaction layer contains silver in a proportion of no more than 5 wt. %, more preferably no more than 1 wt. %, or is even silver-free.

Exposing a surface of the ceramic substrate takes place, for example, in several steps. First, the metal coating is removed, e.g., by etching, and the reaction layer formed during active metal brazing is exposed. The exposed reaction layer is then removed, e.g., by etching or laser ablation. Preferably, the exposed reaction layer is removed using an ultrashort pulse laser (e.g., an IR picosecond or femtosecond laser).

In order to electrically isolate the regions of the metal coating that are separated by the recess, it would be sufficient to carry out the material removal with the pulsed laser only for such a time or under such conditions until the electrically conductive material has been completely removed in the treated regions, but a modification of the silicon nitride on the surface of the ceramic substrate is avoided.

However, within the scope of the present invention, the treatment with the pulsed laser not only exposes the ceramic substrate surface, but also modifies the silicon nitride on the surface of the ceramic substrate. As a result of this modification, the ceramic substrate shows, at least in the region of the recess, an Si2p signal in the XPS spectrum which has additional peaks with maxima in the range of 98.0 to 100.0 eV and 102.5 to 104.0 eV. For the production of a metal-ceramic substrate which has the Si2p signal according to the invention in the XPS spectrum, it has proven advantageous if the pulses of the laser beam have an energy density of at least 2 J/cm², for example in the range of 2 J/cm² to 7 J/cm². The pulse frequency of the laser beam is 1000 kHz, for example. The region of the recess in which the ceramic substrate shows the Si2p signal according to the invention comprises, for example, at least 50%, more preferably at least 70%, of the surface of the ceramic substrate exposed by the recess or may even comprise substantially the entire surface of the ceramic substrate exposed by the recess.

Within the scope of the present invention, it is also possible to expose the ceramic substrate surface by a single- or multi-stage etching process first and then to treat the exposed ceramic substrate surface with the pulsed laser beam until the Si2p signal according to the invention is realized in the XPS spectrum.

However, for reasons of method efficiency, it may be preferable to use the pulsed laser both for exposing the ceramic substrate surface and for modifying the silicon nitride on the surface of the ceramic substrate.

An exposed surface of the ceramic substrate which has the Si2p signal according to the invention in the XPS spectrum shows a higher water wetting angle. This leads to better moisture protection of the metal-ceramic composite.

The present invention also relates to a semiconductor module, containing the metal-ceramic composite described above, one or more semiconductor components.

Preferably, the semiconductor module contains a casting compound, wherein the casting compound contacts the surface of the ceramic substrate of the metal-ceramic composite exposed by the recess.

Casting compounds for electronic components are known to a person skilled in the art. The casting compound contains, for example, a polymer (e.g., a thermoplastic or thermosetting polymer). For example, the casting compound contains an optionally cured epoxy resin or silicone resin, a polyurethane, or an inorganic cement (e.g., a phosphate cement).

### Measurement Methods

### Measuring the XPS Spectra

The recording and evaluation of the XPS energy spectra was carried out as follows: In preparation for the measurements using X-ray photoelectron spectroscopy, the ceramic samples were cut up with edge lengths of 2 (+/−0.1) cm×2 (+/−0.1) cm such that the exposed Si₃N₄ ceramic regions were obtained. The sample pieces were cleaned of dust by blowing on them with nitrogen gas. The sample pieces were glued to a sample holder using non-conductive adhesive tape. The X-ray photoelectron spectra were recorded on a PHI 5800 ESCA from Physical Electronics with an Mg anode (monochromatic Kα=1.253 keV) as the source. First, overview spectra (range 0-1400 eV) of the sample pieces were recorded. From the overview spectra, conclusions were drawn about the elements present on the examined upper side of the sample pieces. Detail spectra of the sample pieces were then recorded in the energy ranges in which signals could be identified in the overview spectrum. To record the detail spectra, an X-ray beam (200 μm diameter; 50 W at 15 kV; measurement time: 25-40 min (for example: 30 min); 20 ms integration time per measurement point) was used with the peak-to-noise setting activated and using a neutralizer (combination of Ar+ and e−, with low kinetic energy). The spectra were evaluated using the analysis software CasaXPS (version 5 2.3.224PR1.0; Casa Software Ltd.). The C—C/C—H component of the C Is signal (ubiquitously present) was normalized to 284.8 eV as a reference, and the binding energies of the detail spectra were shifted accordingly. A Shirley function was used for background correction. Peaks were generated from the obtained signals using the analysis software. The number of peaks was adjusted on the basis of fit models from the literature (XPS-NIST10 database), and the peaks were assigned to elements or compounds. The analysis software was used to calculate the peak areas for the generated peaks, taking into account the relative sensitivity factors.

### Composition of the Adhesion-Promoting Layer

The composition of the adhesion-promoting layer is determined by energy-dispersive X-ray spectroscopy (EDX) coupled with scanning electron microscopy (SEM-EDX).

In SEM-EDX, a focused primary electron beam is guided (scanned) over the sample surface point by point. The scattered electrons are detected using a detector, wherein the number of electrons per pixel results in a microscopic image of the sample surface in grayscale. In addition, the primary electron beam excites the sample to emit characteristic X-ray radiation, and the elements in the sample and their weight proportion can be determined by analyzing the energy spectrum using an EDX detector. For the examination, for example, a scanning electron microscope (JSM-6060 SEM, JEOL Ltd) with a silicon drift EDX detector (NORAN, Thermo Scientific Inc) and analytical software (Pathfinder Mountaineer EDS System, for example Version 2.8, Thermo Scientific Inc) are used. For scanning electron microscopy, the following settings are used: magnification: 1000-fold, acceleration voltage=15 kV, working distance=10 mm, spot size (50-60) (set to reach 25%+/−5% of the dead time of the EDX detector). The EDX spectrum was detected using the following settings of the EDX detector: live time=30 s, rate=auto, low energy cutoff=100 keV, high energy cutoff=auto (per SEM acceleration voltage).

By means of SEM-EDX, the composition of the adhesion-promoting layer can be determined both qualitatively (detection of certain elements and phases, e.g., a metal nitride phase present in the adhesion-promoting layer) and quantitatively. For example, the measurement is carried out at at least 10 points on the adhesion-promoting layer.

### EXAMPLES

Five individual silicon nitride substrates (S1, S2, S3, S4 and S5) were separated from a silicon nitride starting substrate which had predetermined breaking points for separation. The ceramic substrates S1-S5 had matching dimensions (174 mm×139 mm×0.32 mm).

Ceramic substrate S1 was used in comparative example 1 (VB1), ceramic substrate S2 was used in example 1 according to the invention (EB1), ceramic substrate S3 was used in example 2 (EB2) according to the invention, and ceramic substrate S4 was used in comparative example VB2.

For each of the individual silicon nitride substrates S1-S4, the Si2p signal in the XPS spectrum was measured in the region of the front side that is exposed again later after metalization. The XPS-Si2p signal was also measured in the corresponding region on the ceramic surface of substrate S5.

In each of these substrates S1-S5, the Si2p signal in the XPS spectrum showed only one peak. The maxima of these peaks were substantially the same and were at 101.8+/−0.1 eV.

The silicon nitride substrates were metalized by identical active metal brazing processes under the conditions described below.

On one of the sides of the ceramic substrate, an active metal brazing paste was applied by screen printing on an area measuring 168 mm×130 mm and pre-dried for 15 minutes at 125° C. The active metal brazing paste consisted of 67 wt. % copper powder, 19.8 wt. % tin powder, 3.7 wt. % titanium hydride and 9.5 wt. % of an organic vehicle. The paste thickness after pre-drying was 25+/−5 μm. Subsequently, a copper film made of oxygen-free, highly conductive copper with a purity of 99.99% and dimensions of 170 mm×132 mm×0.3 mm was placed on the pre-dried paste. The resulting arrangement was then turned over, the paste was similarly applied to the opposite side of the ceramic substrate by screen printing, pre-dried and fitted with a copper film to obtain a sandwich arrangement. The sandwich arrangement was weighted with a weight of 1 kg, fired at a maximum temperature of 910° C. for 20 minutes, and then cooled to room temperature to obtain an unstructured metal-ceramic composite. Due to the production by active metal brazing, an adhesion-promoting reaction layer is present between the metal coating and the ceramic substrate. This contains titanium (e.g., in the form of a nitride).

Each of the three metal-ceramic composites was subjected to a first structuring process using an etching solution containing CuCl₂. The metal coating in the etched regions on the front side of the ceramic substrate was removed. However, the reaction layer resulting from the active metal brazing process was not removed by the CuCl₂-containing etching solution.

In comparative example VB1, the exposed reaction layer was removed with an etching solution containing ammonium fluoride, fluoroboric acid, and hydrogen peroxide.

In the examples EB1 and EB2 according to the invention and in comparative example VB2, the exposed reaction layer was removed by treatment with an ultrashort pulse laser. The laser pulses of the examples EB1 and EB2 according to the invention had an energy density of 2 J/cm² and 4 J/cm², while in the comparative example VB2 pulses with an energy density of 9 J/cm² were used. The pulse frequency was 1000 kHz in each case.

XPS spectra were recorded on the exposed ceramic surfaces of the examples EB1-EB2 according to the invention and the comparative examples VB1 and VB2, and the wetting angles with water were determined.

The determination of the wetting angle was carried out using the OCA 15EC contact angle measuring device from Dataphysics. Three test liquids were used for the determination: distilled water, CH212 (diiodomethane) and C2H4 (OH) 2 anhydrous ethylene glycol. For each liquid, contact angles were measured using at least 20 droplets in order then to ascertain an average value.

The XPS spectra were evaluated with regard to the Si2p signal.

The results are summarized in the following table 1.

TABLE 1
XPS-Si2p signals of the silicon nitride surface
and wetting angle with water

| | Si2p signal | | | |
|---|---|---|---|---|
| | | 101.0- | 102.5- | Wetting angle |
| Example | 98.0-100.0 eV | 102.2 eV | 103.5 eV | with water |
| Starting | No peak | 1 peak present | No peak | n.d. |
| substrate | | | | |
| VB1 | No peak | 1 peak present | No peak | 45° |
| VB2 | No peak | 1 peak present | 1 peak | 49° |
| | | | present | |
| EB1 | 1 peak present | 1 peak present | 1 peak | 61° |
| | | | present | |
| EB2 | 1 peak present | 1 peak present | 1 peak | 69° |
| | | | present | |

By treatment with the pulsed laser, the silicon nitride substrates in the examples EB1 and EB2 according to the invention were modified in their structure and therefore show a significantly different Si2p signal in comparison with the starting substrate and the substrate exposed by etching.

The silicon nitride substrate of the comparative example VB2 also shows a changed Si2p signal in the XPS spectrum in comparison with the original substrate due to the treatment with the pulsed laser. However, this Si2p signal is not according to the invention because it does not have a peak with a maximum in the range of 98.0 to 100.0 eV.

The silicon nitride surfaces having the Si2p signal according to the invention show a significantly higher water wetting angle in comparison with the silicon nitride surfaces of the comparative examples. This leads to better moisture protection of the silicon nitride ceramic.

1. A metal-ceramic composite, containing a ceramic substrate comprising a front side and a rear side and containing silicon nitride, a metal coating on the front side of the ceramic substrate, wherein the metal coating has at least one recess, and a surface of the ceramic substrate is exposed by the recess, the ceramic substrate shows an Si2p signal in the range of 96 to 107 eV in an energy spectrum recorded by X-ray photoelectron spectroscopy, at least in the region of the recess, wherein the Si2p signal has the following:
one or more peaks that each have a maximum in the range of 98.0 to 100.0 eV,
one or more peaks that each have a maximum in the range of 101.0 to 102.2 eV,
one or more peaks that each have a maximum in the range of 102.5 to 104.0 eV.

2. The metal-ceramic composite according to claim 1, wherein the following relationships are satisfied:
$${I}_{1} / {I}_{ges} \geq 0.02 ;$$
$$2. \leq {I}_{2} / {I}_{1} \leq 8. ;$$
$$with the proviso that$$
$$( {I}_{1} + {I}_{2} ) / {I}_{ges} \leq 0 \text{.85} ;$$
$$( {I}_{1} + {I}_{2} + {I}_{3} ) / {I}_{ges} \geq 0 \text{.95} ;$$
wherein
I_{ges} is the total intensity of the Si2p signal;
I₁ is the total intensity of the peaks that each have a maximum in the range of 98.0-100.0 eV;
I₂ is the total intensity of the peaks that each have a maximum in the range of 101.0-102.2 eV;
I₃ is the total intensity of the peaks that each have a maximum in the range of 102.5-104.0 eV.

3. The metal-ceramic composite according to claim 1, wherein in the ranges of 98.0 to 100.0 eV, 101.0 to 102.2 eV and 102.5 to 104.0 eV there are no more than two peaks with maxima in the relevant range.

4. The metal-ceramic composite according to claim 1, wherein the ceramic substrate contains the silicon nitride in a proportion of at least 70 wt. %.

5. The metal-ceramic composite according to claim 1, wherein the metal coating is a copper or aluminum coating.

6. The metal-ceramic composite according to claim 1, wherein a reaction layer is present between the ceramic substrate and the metal coating, wherein the reaction layer contains one or more elements ERS selected from Ti, Hf, Zr, Nb, V, Ta, and Ce.

7. A semiconductor module, containing the metal-ceramic composite according to claim 1, one or more semiconductor components.

8. The semiconductor module according to claim 1, further containing a casting compound, wherein the casting compound contacts the surface of the ceramic substrate of the metal-ceramic composite exposed by the recess.
